(19) United States
(12) Patent Application Publication
(10) Pub. No.: US 2026/0040946 A1
(43) Pub. Date: Feb. 5, 2026

(54) SEMICONDUCTOR PACKAGE

(71) Applicant: Samsung Electronics Co., Ltd., Suwon-si (KR)

(72) Inventor: Wonjung JANG, Suwon-si (KR)

(73) Assignee: Samsung Electronics Co., Ltd., Suwon-si (KR)

(21) Appl. No.: 19/020,183

(22) Filed: Jan. 14, 2025

(30) Foreign Application Priority Data
Aug. 2, 2024 (KR) 10-2024-0103323

(51) Int. Cl. H01L 23/00; H01L 25/07

(52) U.S. Cl. CPC H01L 23/562; H01L 24/32; H01L 24/73; H01L 24/83; H01L 25/071; H01L 24/16; H01L 2224/16146; H01L 2224/32145; H01L 2224/73204; H01L 2224/83007; H01L 2224/83203; H01L 2225/06513; H01L 2225/06517; H01L 2225/06541; H01L 2225/06589

(57) ABSTRACT

A semiconductor package may include a first semiconductor chip extending in a horizontal direction, a first chip stack and a second chip stack, on the first semiconductor chip and horizontally spaced apart from each other, a supporting structure on the first semiconductor chip and interposed between the first and second chip stacks, a first adhesive layer disposed on the first semiconductor chip in contact with the first chip stack and the supporting structure, and a second adhesive layer disposed on the first semiconductor chip in contact with the second chip stack and the supporting structure. Each of the first and second chip stacks may include second semiconductor chips stacked in a vertical direction. Each of the first and second semiconductor chips may include a penetration via. The first and second adhesive layers may be spaced apart from each other with the supporting structure interposed therebetween.

### CROSS-REFERENCE TO RELATED APPLICATIONS

This U.S. non-provisional patent application claims priority under 35 U.S.C. § 119 to Korean Patent Application No. 10-2024-0103323, filed on Aug. 2, 2024, in the Korean Intellectual Property Office, the entire contents of which are hereby incorporated by reference.

### BACKGROUND OF THE INVENTION

Some example embodiments relate to a semiconductor package.

Due to the rapid development of the electronic industry and the increase in the diversity of user desires, electronic devices have reduced in sizes and have included more functions. Accordingly, semiconductor devices used in the electronic devices have reduced in size and have included more functions. To this end, a semiconductor package technology has been proposed in which a plurality of vertically stacked semiconductor chips are connected using through-silicon vias (TSVs).

### SUMMARY

Some example embodiments provide a semiconductor package with improved reliability.

Alternatively or additionally, some example embodiments provide a semiconductor package with improved durability.

According some example embodiments, a semiconductor package may include a first semiconductor chip extending in a horizontal direction, a first chip stack and a second chip stack, the first and second chip stacks on the first semiconductor chip and horizontally spaced apart from each other, a supporting structure on the first semiconductor chip and interposed between the first and second chip stacks, a first adhesive layer on the first semiconductor chip in contact with the first chip stack and the supporting structure, and a second adhesive layer on the first semiconductor chip in contact with the second chip stack and the supporting structure. Each of the first and second chip stacks may include one or more second semiconductor chips stacked in a vertical direction. Each of the first and second semiconductor chips may include a penetration via. The first and second adhesive layers may be spaced apart from each other with the supporting structure interposed therebetween.

Alternatively or additionally according to some example embodiments, a semiconductor package may include a first semiconductor chip including a plurality of first penetration vias, a first chip stack and a second chip stack, the first and second chip stacks on the first semiconductor chip and spaced apart from each other in a first direction parallel to a top surface of the first semiconductor chip, a supporting structure on the first semiconductor chip and interposed between the first and second chip stacks, a first adhesive layer on the first semiconductor chip in direct contact with the first chip stack and the supporting structure, a second adhesive layer disposed on the first semiconductor chip in direct contact with the second chip stack and the supporting structure, and a molding layer in direct contact with the first and second adhesive layers. Each of the first and second chip stacks may include one or more second semiconductor chips stacked in a second direction perpendicular to the top surface of the first semiconductor chip. Each of the second semiconductor chips may include a plurality of second penetration vias, when viewed in a plan view. The first adhesive layer may include a first portion interposed between the molding layer and the first chip stack and a second portion interposed between the supporting structure and the first chip stack. A largest value of a first width of the first portion in the first direction may be larger than a second width of the second portion in the first direction.

Alternatively or additionally according to some example embodiments, a semiconductor package may include a first semiconductor chip including a plurality of first penetration vias, a first chip stack and a second chip stack, the first and second chip stacks on the first semiconductor chip and spaced apart from each other in a first direction parallel to a top surface of the first semiconductor chip, a supporting structure on the first semiconductor chip and interposed between the first and second chip stacks, a first adhesive layer on the first semiconductor chip in direct contact with the first chip stack and the supporting structure, a second adhesive layer on the first semiconductor chip in direct contact with the second chip stack and the supporting structure, and a molding layer in direct contact with the first and second adhesive layers. Each of the first and second chip stacks may include two or more second semiconductor chips stacked in a second direction perpendicular to the top surface of the first semiconductor chip, and one or more chip terminals interposed between the second semiconductor chips. Each of the second semiconductor chips may include a plurality of second penetration vias. The first adhesive layer may include a first portion interposed between the molding layer and the first chip stack and a second portion interposed between the supporting structure and the first chip stack, when viewed in the first direction. At a level overlapped with the chip terminals, a width of the first portion in the first direction may be larger than a width of the second portion in the first direction.

### BRIEF DESCRIPTION OF THE DRAWINGS

FIG. 1 is a plan view illustrating a semiconductor package according to some example embodiments.

FIG. 2 is a sectional view taken along a line A-A′ of FIG. 1.

FIG. 3 is a plan view illustrating a chip structure of FIG. 1.

FIGS. 4A and 4B are sectional views taken along a line B-B′ of FIG. 3.

FIGS. 5A to 5D illustrate a method of fabricating a semiconductor package according to some example embodiments.

FIGS. 6A to 6E illustrate a method of fabricating a memory chip stack in a semiconductor package according to some example embodiments.

### DETAILED DESCRIPTION

Some example embodiments will now be described more fully with reference to the accompanying drawings, in which example embodiments are shown.

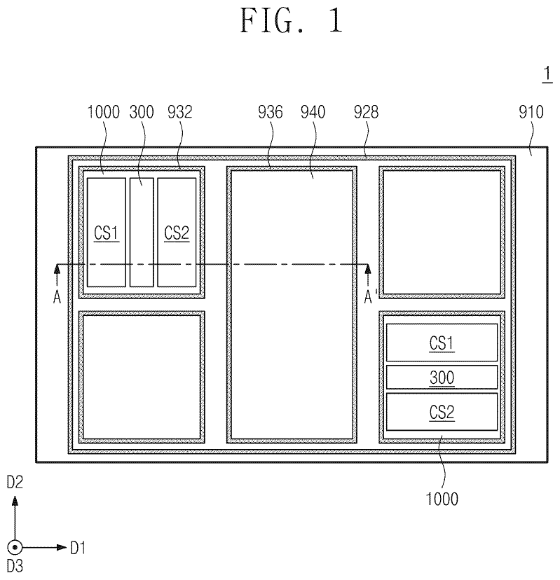

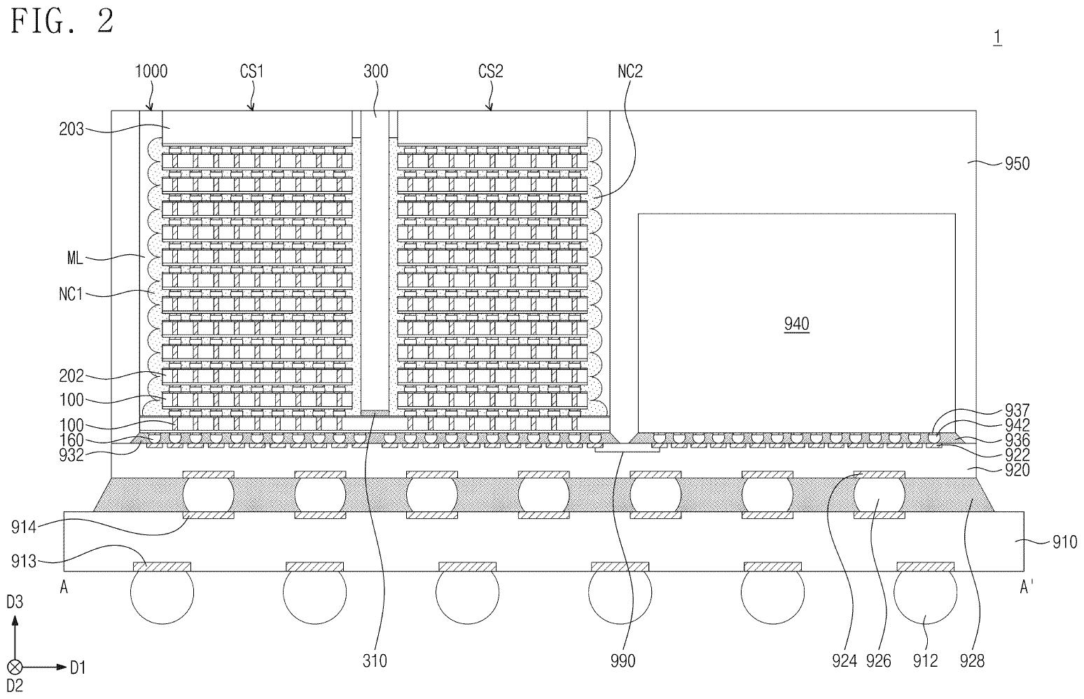

FIG. 1 is a plan view illustrating a semiconductor package according to some example embodiments. FIG. 2 is a sectional view taken along a line A-A′ of FIG. 1.

Referring to FIGS. 1 and 2, a semiconductor package 1 may include a package substrate 910, an interposer substrate 920, a chip structure 1000, and a host 940.

The package substrate 910 may be or include (or be included in), for example, a printed circuit board (PCB). Alternatively or additionally, the package substrate 910 may have a structure, in which insulating layers and interconnection layers are alternately stacked, although not shown. The package substrate 910 may include a plurality of lower substrate pads 913 on a bottom surface thereof and a plurality of upper substrate pads 914 on a top surface thereof.

First outer connection terminals 912 may be disposed on the lower substrate pads 913, respectively. The first outer connection terminals 912 may include solder balls and/or solder bumps. In some cases, for example, depending on the kind or arrangement of the first outer connection terminals 912, the semiconductor package may have a ball-grid array (BGA) structure, a fine ball-grid array (FBGA) structure, or a land grid array (LGA) structure. The first outer connection terminal 912 may be formed of or include an alloy that contains at least one of tin (Sn), silver (Ag), copper (Cu), nickel (Ni), bismuth (Bi), indium (In), antimony (Sb), or cerium (Ce).

The interposer substrate 920 may be provided on the package substrate 910. The interposer substrate 920 may be or may include, for example, a silicon interposer substrate. The interposer substrate 920 may include a lower interposer pad 924, which is provided on a bottom surface thereof, and an upper interposer pad 922 and a metal line 990, which are provided on a top surface thereof. The chip structure 1000 and the host 940 may be electrically connected to the package substrate 910 through the interposer substrate 920.

First connection terminals 926 may be disposed between the package substrate 910 and the interposer substrate 920. In detail, the first connection terminals 926 may be interposed between the upper substrate pad 914 and the lower interposer pad 924 and may be in contact with the upper substrate pad 914 and the lower interposer pad 924. The interposer substrate 920 may be electrically connected to the package substrate 910 through the first connection terminals 926. The first connection terminals 926 may include a metallic material that is substantially the same as or similar to that of the first outer connection terminal 912.

A first under-fill layer 928 may be provided between the package substrate 910 and the interposer substrate 920. The first under-fill layer 928 may be provided to fill a space between the package substrate 910 and the interposer substrate 920 and enclose a side surface of each of the first connection terminals 926. The first under-fill layer 928 may further include, for example, an epoxy resin; example embodiments are not limited thereto.

The chip structure 1000 and the host 940 may be disposed on the interposer substrate 920, e.g., may be disposed adjacent or near to each other. In detail, the chip structure 1000 may include a plurality of chip stacks which are spaced apart from each other in a first direction D1 parallel to a top surface of the package substrate 910, with the host 940 interposed therebetween. In some example embodiments, a plurality of chip structures 1000 may be provided to be spaced apart from each other in a second direction D2 perpendicular to the first direction D1. The arrangement of the chip structure 1000 and/or of the host 940 may be variously changed depending on the type or design of the semiconductor package.

The chip structure 1000 may include a first chip stack CS1, a second chip stack CS2, and a supporting structure 300, which will be described below. As shown in FIG. 1, the first chip stack CS1, the second chip stack CS2, and the supporting structure 300 may be disposed to be spaced apart from each other in the first or second direction D1 or D2.

A second under-fill layer 932 may be provided between the chip structure 1000 and the interposer substrate 920. The second under-fill layer 932 may fill a space between the chip structure 1000 and the interposer substrate 920 and may enclose a side surface of each of second connection terminals 160, which will be described below. The second under-fill layer 932 may include, for example, an epoxy resin, e.g., the same or different epoxy resin included in the first underfill layer 928.

The host 940 may be disposed on the interposer substrate 920. The host 940 may include one or more of a graphics processing unit (GPU) die, a central processing unit (CPU) die, or a system-on-chip (SoC). In some example embodiments, the host 940 may be a logic chip.

A host pad 937 may be disposed on a bottom surface of the host 940. Third connection terminals 942 may be disposed between the host 940 and the interposer substrate 920. In detail, the third connection terminals 942 may be interposed between the host pad 937 and the upper interposer pad 922 and may be in contact with the host pad 937 and the upper interposer pad 922. The host 940 may be electrically connected to the package substrate 910 through the third connection terminals 942. The third connection terminals 942 may include a metallic material that is substantially the same as or similar to that of the first outer connection terminal 912.

A third under-fill layer 936 may be provided between the host 940 and the interposer substrate 920. The third under-fill layer 936 may fill a space between the host 940 and the interposer substrate 920 and may enclose a side surface of each of the third connection terminals 942. The third under-fill layer 936 may include, for example, an epoxy resin, e.g., the same as or different from the epoxy resin included in either or both of the first under-fill layer 928 and the second under-fill layer 932.

A mold layer 950 may be disposed on the interposer substrate 920. In detail, the mold layer 950 may cover a top surface of the interposer substrate 920. The mold layer 950 may enclose the chip structure 1000 and the host 940. A level of a top surface of the mold layer 950 may be substantially equal to a level of a top surface of the chip structure 1000. The mold layer 950 may include an insulating material, and in some example embodiments, the insulating material may include an epoxy molding compound and/or an adhesive material.

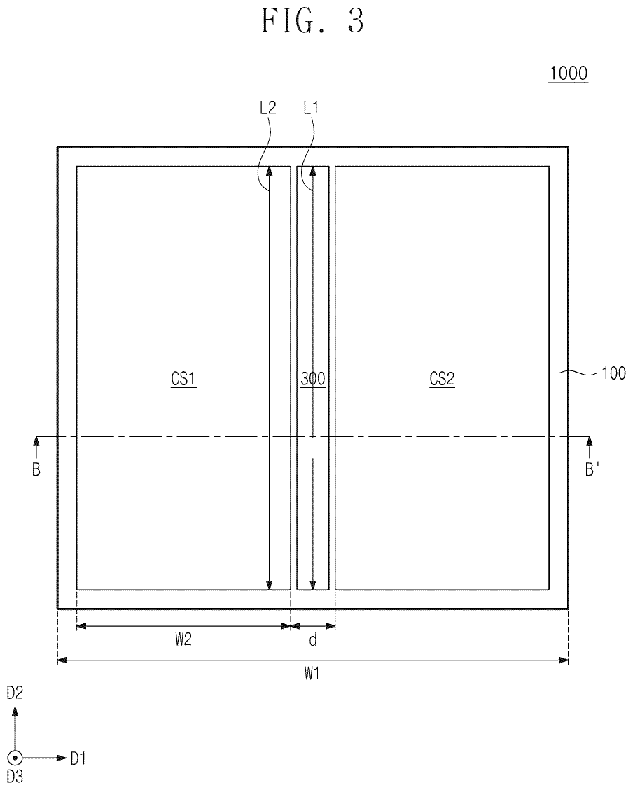

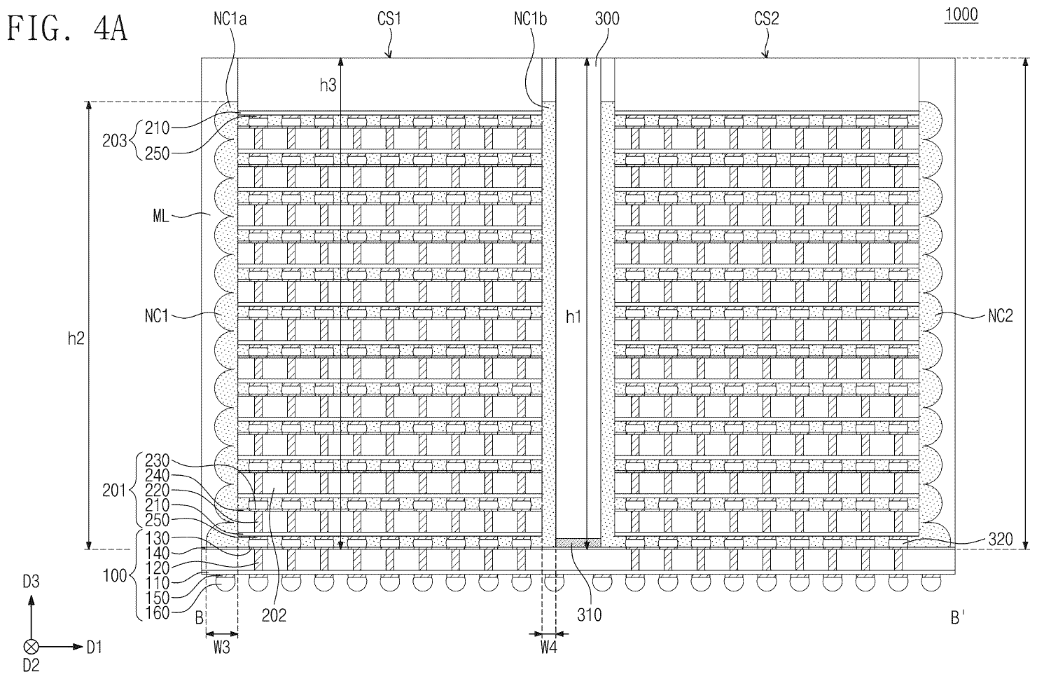

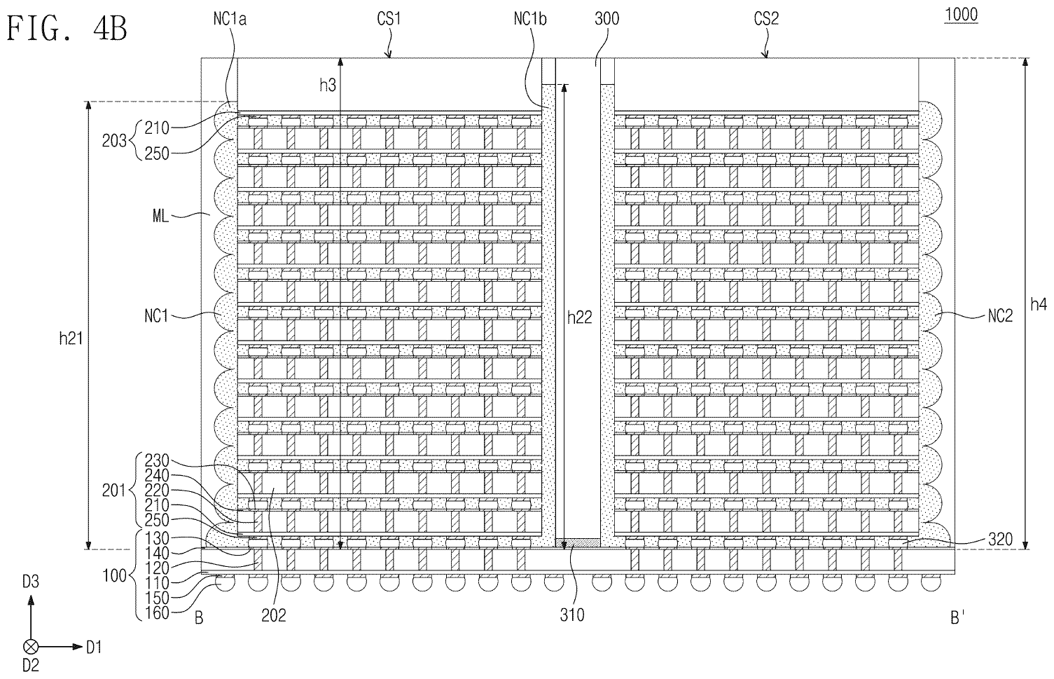

FIG. 3 is a plan view illustrating a chip structure of FIG. 1. FIGS. 4A and 4B are sectional views taken along a line B-B′ of FIG. 3.

A chip structure or a semiconductor package 1000 according to some example embodiments may include a first semiconductor chip 100, the first chip stack CS1, the second chip stack CS2, the supporting structure 300, a first adhesive layer NC1, a second adhesive layer NC2, and a molding layer ML.

Referring to FIGS. 3 and 4A, the first semiconductor chip 100 may be provided to extend in the first direction D1 and the second direction D2, which are perpendicular to each other. In some example embodiments, the first semiconductor chip 100 may be or may include a logic chip. The first semiconductor chip 100 may include an integrated circuit provided therein. In detail, the first semiconductor chip 100 may be or may include a semiconductor chip including an electronic device (e.g., a transistor and/or a diode). The first semiconductor chip 100 may include a memory controller. For example, the first semiconductor chip 100 may include integrated circuits, which are configured to control operations of memory chips to be described below.

The first semiconductor chip 100 may include a first circuit layer 110, a first penetration via 120, a first upper pad 130, a first protection layer 140, a first lower pad 150, and a connection terminal 160.

The first circuit layer 110 may be provided below the first semiconductor chip 100 and may include a circuit and an interconnection structure, although not shown. The first penetration via 120 may be provided to vertically penetrate the first semiconductor chip 100. For example, the first penetration via 120 may connect the first upper pad 130 to the circuit and/or the interconnection structure of the first circuit layer 110. In some example embodiments, a plurality of first penetration vias 120 may be provided. In some example embodiments, for example if necessary or desirable, an insulating layer (not shown) may be provided to enclose the first penetration via 120. For example, the insulating layer may be formed of or include at least one of silicon oxide (SiO), silicon nitride (SiN), silicon oxynitride (SiON), or low-k dielectric materials.

The first upper pad 130 may be disposed on a top surface of the first semiconductor chip 100. The first upper pad 130 may be coupled to the first penetration via 120. In some example embodiments, a plurality of first upper pads 130 may be provided. In this case, the first upper pads 130 may be coupled to the first penetration vias 120, respectively, and the first upper pads 130 may be arranged in the same shape as the first penetration vias 120. The first upper pad 130 may be coupled to the first circuit layer 110 through the first penetration via 120. The first upper pad 130 may be formed of or include at least one of metallic materials (e.g., copper (Cu), aluminum (Al), and/or nickel (Ni)).

The first protection layer 140 may be disposed on the top surface of the first semiconductor chip 100 to enclose the first upper pad 130. The first protection layer 140 may be provided to expose the first upper pad 130. The first semiconductor chip 100 may be protected by the first protection layer 140. The first protection layer 140 may be or may include an insulating layer, such as a silicon oxide layer and/or a silicon nitride layer.

The first lower pad 150 may be disposed on a bottom surface of the first semiconductor chip 100. In more detail, the first lower pad 150 may be disposed on a bottom surface of the first circuit layer 110. The first lower pad 150 may be electrically connected to the circuit and/or the interconnection structure of the first circuit layer 110. In some example embodiments, a plurality of first lower pads 150 may be provided. The first lower pad 150 may be formed of or include at least one of metallic materials (e.g., copper (Cu), aluminum (Al), and/or nickel (Ni)).

A plurality of the second connection terminals 160 may be provided on the bottom surface of the first semiconductor chip 100. Each of the second connection terminals 160 may be disposed on the first lower pad 150. Referring to FIG. 4A in conjunction with FIG. 2, the second connection terminals 160 may be interposed between the first lower pad 150 and the upper interposer pad 922 to connect the first lower pad 150 to the upper interposer pad 922.

The second connection terminals 160 may include solder balls and/or solder bumps. In some example embodiments, for example, depending on the kind and arrangement of the second connection terminals 160, the semiconductor package may have a ball-grid array (BGA) structure, a fine ball-grid array (FBGA) structure, or a land grid array (LGA) structure. The connection terminal 160 may be formed of or include an alloy that contains at least one of tin (Sn), silver (Ag), copper (Cu), nickel (Ni), bismuth (Bi), indium (In), antimony (Sb), or cerium (Ce).

Referring back to FIGS. 3 and 4A, the first chip stack CS1 and the second chip stack CS2 may be provided on the top surface of the first semiconductor chip 100. Each of the first and second chip stacks CS1 and CS2 may include a plurality of semiconductor chips, and in some example embodiments, the semiconductor chips may be or may include memory chips. In some example embodiments, a number of semiconductor chips included int eh first chip stack CS1 may be the same as, or different from (e.g., greater than or less than), a number of semiconductor chips included in the second semiconductor stack CS2. In some example embodiments, a kind of chips included in the first semiconductor stack CS1 may be the same as or different from a kind of chips included in the second semiconductor stack CS2. The semiconductor chips may be stacked in a third direction D3 that is perpendicular to the first and second directions D1 and D2. The first and second chip stacks CS1 and CS2 may be spaced apart from each other in the first direction D1.

The semiconductor chips of each of the first and second chip stacks CS1 and CS2 may include a lower semiconductor chip 201, an intermediate semiconductor chip 202, and an upper semiconductor chip 203. Each of the lower semiconductor chip 201, the intermediate semiconductor chip 202, and the upper semiconductor chip 203 may be or may include a memory chip. Each of the memory chips may be a DRAM chip and/or a NAND FLASH chip. For example, the first semiconductor stack CS1 may include one of a DRAM or a NAND FLASH chip, and the second semiconductor stack may also include the one of the DRAM or NAND FLASH chip and/or the other of the DRAM or NAND FLASH chip.

The lower semiconductor chip 201 may refer to a semiconductor chip in direct contact with the first semiconductor chip 100. The intermediate and upper semiconductor chips 202 and 203 may be sequentially stacked on the lower semiconductor chip 201.

Ten intermediate semiconductor chips 202 (a total of 12 layers) may be provided, as shown in FIG. 1B, but the number of the intermediate semiconductor chips 202 is not limited to this example. For example, the intermediate semiconductor chip 202 may not be provided, may be provided alone, or may be provided in multiples. As an example, two intermediate semiconductor chips 202 (a total of 4 layers), 6 intermediate semiconductor chips 202 (a total of 8 layers), or 14 intermediate semiconductor chips 202 (a total of 16 layers) may be provided. In some example embodiments, the number of the intermediate semiconductor chips 202 in the first chip stack CS1 may be equal to that in the second chip stack CS2; example embodiments are not limited thereto.

The lower semiconductor chip 201 may have a second circuit layer 210 facing the first semiconductor chip 100. For example, the second circuit layer 210 may include a memory circuit. In some example embodiments, a bottom surface of the lower semiconductor chip 201 may be an active surface.

The lower semiconductor chip 201 may have a second protection layer 240 opposite to the second circuit layer 210. The second protection layer 240 may protect the lower semiconductor chip 201. The second protection layer 240 may be an insulating layer, such as a silicon oxide layer or a silicon nitride layer.

The lower semiconductor chip 201 may include a second penetration via 220, which is provided to penetrate a portion of the lower semiconductor chip 201 in a direction from the second protection layer 240 toward the second circuit layer 210. In some example embodiments, a plurality of second penetration vias 220 may be provided. An insulating layer (not shown) may be provided to enclose the second penetration via 220. For example, the insulating layer may be formed of or include at least one of silicon oxide (SiO), silicon nitride (SiN), silicon oxynitride (SiON), or low-k dielectric materials. The second penetration via 220 may be electrically connected to the second circuit layer 210.

A second upper pad 230 may be disposed in the second protection layer 240. The second upper pad 230 may have a top surface that is exposed from the second protection layer 240. The second upper pad 230 may be connected to the second penetration via 220. A second lower pad 250 may be disposed on the second circuit layer 210. In detail, the second lower pad 250 may be disposed on a bottom surface of the second circuit layer 210. The second lower pad 250 may be coupled to the second circuit layer 210. The second upper pad 230 and the second lower pad 250 may be electrically connected to the second circuit layer 210 by the second penetration via 220. In some example embodiments, a plurality of second upper pads 230 and a plurality of second lower pads 250 may be provided. The second upper pad 230 and the second lower pad 250 may be formed of or include at least one of metallic materials (e.g., copper (Cu), aluminum (Al), and/or nickel (Ni)).

The intermediate semiconductor chip 202 may have substantially the same structure as the lower semiconductor chip 201. For example, the intermediate semiconductor chip 202 may include the second circuit layer 210, which is provided to face the first semiconductor chip 100, the second protection layer 240, which is opposite to the second circuit layer 210, the second penetration via 220, which is extended in a direction from the second protection layer 240 to the second circuit layer 210 to penetrate the intermediate semiconductor chip 202, the second upper pad 230, which is provided in the second protection layer 240, and the second lower pad 250, which is provided on the second circuit layer 210.

The upper semiconductor chip 203 may have a substantially similar structure as the lower semiconductor chip 201. For example, the upper semiconductor chip 203 may include the second circuit layer 210, which is provided to face the first semiconductor chip 100, and the second lower pad 250, which is provided on the second circuit layer 210. As shown in FIGS. 4A and 4B, the upper semiconductor chip 203 may not have the second penetration via 220, the second upper pad 230, and the second protection layer 240. However, example embodiments are not limited thereto. For example, in some example embodiments, the upper semiconductor chip 203 may include at least one of the second penetration via 220, the second upper pad 230, and the second protection layer 240. The upper semiconductor chip 203 may have a thickness larger than the lower and intermediate semiconductor chips 201 and 202.

Each of the first and second chip stacks CS1 and CS2 may have a width in the first direction D1, a length in the second direction D2, and a height in the third direction D3. A width W2, a length L2, and a height h3 of the first chip stack CS1 may be substantially equal to a width, a length, and a height of the second chip stack CS2; example embodiments are not limited thereto. In some example embodiments, a width W1 of the first semiconductor chip 100 in the first direction D1 may be larger than two times the width W2 of the first chip stack CS1.

The first semiconductor chip 100 may be connected to one semiconductor chip, which is included in the chip stack CS1 or CS2 and is adjacent to the same, by chip terminals 320. The chip terminals 320 may be solder balls that are formed of an alloy containing at least one of tin (Sn), silver (Ag), copper (Cu), nickel (Ni), bismuth (Bi), indium (In), antimony (Sb), or cerium (Ce).

In detail, at least one of the chip terminals 320 may be disposed between the first upper pad 130 of the first semiconductor chip 100 and the second lower pad 250 of the lower semiconductor chip 201. Some of the chip terminals 320 may be disposed between the second upper pad 230 of the lower semiconductor chip 201 and the second lower pad 250 of the intermediate semiconductor chip 202. The others of the chip terminals 320 may be disposed between the second upper pad 230 of the intermediate semiconductor chip 202 and the second lower pad 250 of the upper semiconductor chip 203.

At least one of the chip terminals 320 may electrically connect the first semiconductor chip 100 to the lower semiconductor chip 201. At least one of the chip terminals 320 may electrically connect the lower semiconductor chip 201 to the intermediate semiconductor chip 202. The others of the chip terminals 320 may electrically connect the intermediate semiconductor chip 202 to the upper semiconductor chip 203.

The supporting structure 300 may be disposed on the first semiconductor chip 100. Referring to FIG. 1, the supporting structure 300 may be disposed between the first and second chip stacks CS1 and CS2 in the first direction D1.

The supporting structure 300 may be a dummy die, which does not include a circuit. In some example embodiments, the supporting structure 300 may have a thermal expansion coefficient (CTE) smaller than the first adhesive layer NC1, the second adhesive layer NC2, and/or the molding layer ML. The supporting structure 300 may include, for example, bulk silicon (Si) or glass. In some example embodiments, the supporting structure 300 may be or may include a single crystalline silicon substrate.

The supporting structure 300 may have a width W in the first direction D1, may have a length L1 in the second direction D2, and may have a height h1 in the third direction D3. The height h1 of the supporting structure 300 may be equal to or smaller than the height h3 of the first chip stack CS1. The length L1 of the supporting structure 300 may be equal to or larger than the length L2 of the first chip stack CS1.

A third adhesive layer 310 may be interposed between the supporting structure 300 and the first semiconductor chip 100 in the third direction D3, but the inventive concept is not limited to this example. In some example embodiments, the third adhesive layer 310 may be omitted. The third adhesive layer 310 may include an adhesive material (e.g., a die attach film (DAF)).

The supporting structure 300 may have two surfaces, which are opposite and parallel to each other, in the first direction D1. One of the two surfaces of the supporting structure 300 may be in direct contact with the first adhesive layer NC1. The other of the two surfaces of the supporting structure 300 may be in direct contact with the second adhesive layer NC2.

The first and second adhesive layers NC1 and NC2 may be disposed on the first semiconductor chip 100. The first and second adhesive layers NC1 and NC2 may be spaced apart from each other in the first direction D1, with the supporting structure 300 interposed therebetween. Each of the first and second adhesive layers NC1 and NC2 may cover the side surfaces of the lower and intermediate semiconductor chips 201 and 202 and may cover a portion of the side surface of the upper semiconductor chip 203. Each of the first and second adhesive layers NC1 and NC2 may be provided to fill spaces between the first and lower semiconductor chips 100 and 201, between the lower and intermediate semiconductor chips 201 and 202, and between the intermediate and upper semiconductor chips 202 and 203. Each of the first and second adhesive layers NC1 and NC2 may enclose side surfaces of the chip terminals 320, which are disposed between the first and lower semiconductor chips 100 and 201, between the lower and intermediate semiconductor chips 201 and 202, and between the intermediate and upper semiconductor chips 202 and 203. For example, each of the first and second adhesive layers NC1 and NC2 may be provided to fill empty spaces between the chip terminals 320 and between the afore-described chips. In some example embodiments, an edge of the first and/or second adhesive layer NC1 and NC2 may be rounded; example embodiments are not limited thereto.

Each of the first and second adhesive layers NC1 and NC2 may include a non-conductive adhesive material, and may or may not include the same adhesive material. Each of the first and second adhesive layers NC1 and NC2 may independently or concurrently be formed from one of a non-conductive film (NCF) or a non-conductive adhesive paste agent (NCP).

The height h1 of the supporting structure 300 may be equal to or larger than a height h2 of the first adhesive layer NC1.

The molding layer ML may be disposed on the first semiconductor chip 100. The molding layer ML may cover the first adhesive layer NC1, the second adhesive layer NC2, and a portion of the side surface of the upper semiconductor chip 203. A level of the molding layer ML may be substantially equal to a level of a top surface of the upper semiconductor chip 203. The molding layer ML may include an insulating material and may include at least one of an epoxy molding compound (EMC) and an adhesive material.

In detail, the molding layer ML may cover side surfaces of the first and second adhesive layers NC1 and NC2, which are not in contact with the supporting structure 300, and may cover portions of the side surfaces of the upper semiconductor chips 203, which are not in contact with the first and second adhesive layers NC1 and NC2.

The top surface of the molding layer ML and the top surface of the upper semiconductor chip 203 may be exposed, e.g., exposed to the outside. A height h4 of the molding layer ML may be substantially equal to the height h3 of the first chip stack CS1 and the height of the second chip stack CS2. The height h1 of the supporting structure 300 may be equal to or smaller than the height h4 of the molding layer ML. Depending on the height h1 of the supporting structure 300, a top surface of the supporting structure 300 may be exposed to the outside or may be covered with the molding layer ML.

Referring to FIG. 4A, the first adhesive layer NC1 may include a first portion NC1a, which is interposed between the molding layer ML and the first chip stack CS1, and a second portion NC1b, which is interposed between the supporting structure 300 and the first chip stack CS1, when viewed in the first direction D1. Between the molding layer ML and the first chip stack CS1, the first portion NC1a may have a first width W3 in the first direction D1. Between the supporting structure 300 and the first chip stack CS1, the second portion NC1b may have a second width W4 in the first direction D1.

The first width W3 may vary depending on the level in the third direction D3 and may have the largest value at a level overlapped with the chip terminals 320. The largest value of the first width W3 may be larger than the second width W4. At a level overlapped with the chip terminals 320, the first width W3 may be larger than the second width W4. At the same level, the first width W3 may be larger than the second width W4. The second width W4 may be equal to or less than 200 μm; example embodiments are not limited thereto.

An interface between the first portion NC1a and the molding layer ML may have a wavy structure or an uneven structure. By contrast, an interface between the second portion NC1b and the supporting structure 300 may have a wavy or uneven structure, which has a relatively small width, and may have a planar or flat structure.

Similar to the first chip stack CS1, the second chip stack CS2 may also have a first portion and a second portion, which are configured to have substantially the same features as those in the first chip stack CS1.

Referring to FIG. 4A, the first portion NC1a may have substantially the same heigh (e.g., the height h2) of the second portion NC1b. However, example embodiments are not limited thereto, and for example, the first portion NC1a and the second portion NC1b may have a height h21 and a height h22, respectively, which are different from each other, as shown in FIG. 4B. The height h22 of the second portion NC1b may be larger than the height of the first portion NC1a.

In the semiconductor package according to some example embodiments, the supporting structure 300 may be interposed between the chip stacks CS1 and CS2. The supporting structure 300 may prevent the semiconductor package from being bent or warped by heat generated from the chip stacks CS1 and CS2 and may prevent the memory chips from being disconnected from each other. As a result, the reliability of the semiconductor package may be improved.

Alternatively or additionally, due to the presence of the supporting structure 300, the adhesive layer NC1 or NC2, which is included in each memory chip stack and is in contact with the supporting structure 300, may be flat. In this case, it may be possible to prevent or suppress or reduce a likelihood of and/or an impact of a void from being formed between the adhesive layers NC1 and NC2. As a result, the durability of the semiconductor package may be improved.

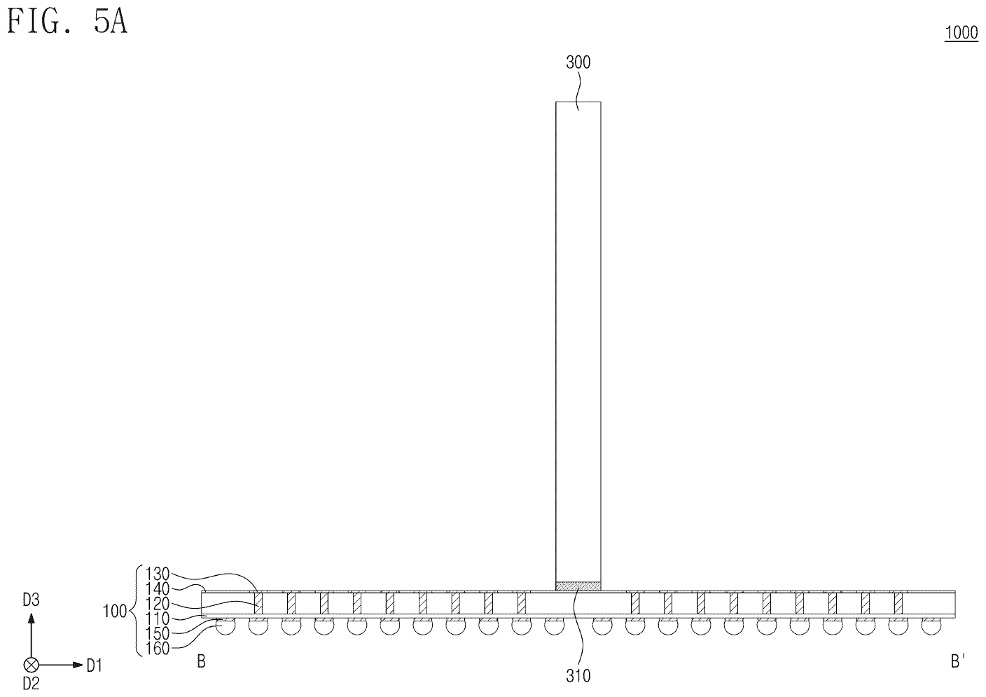

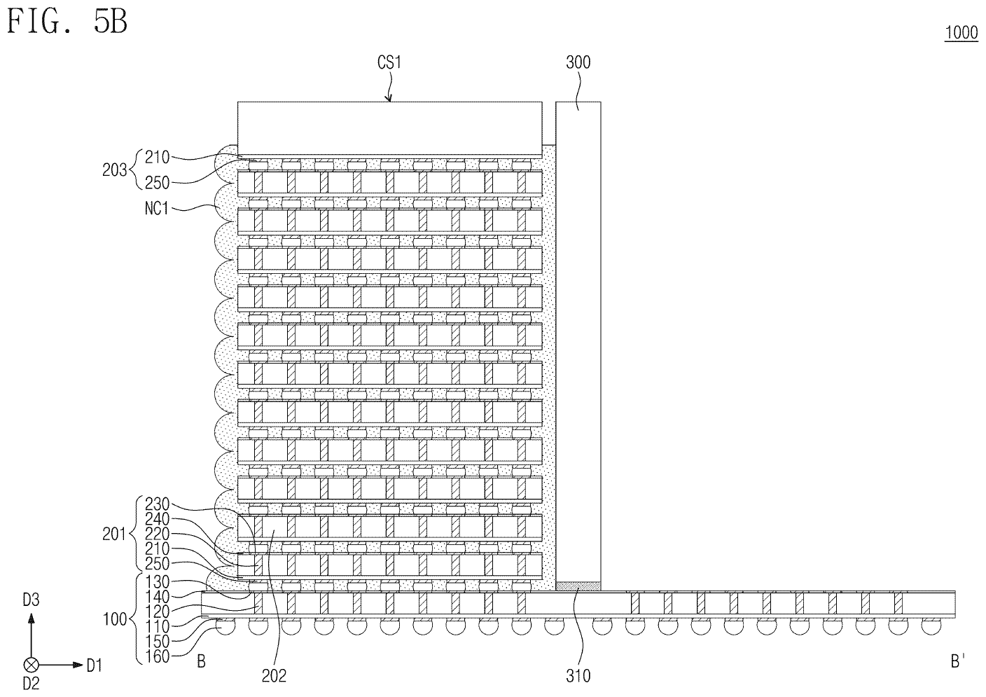

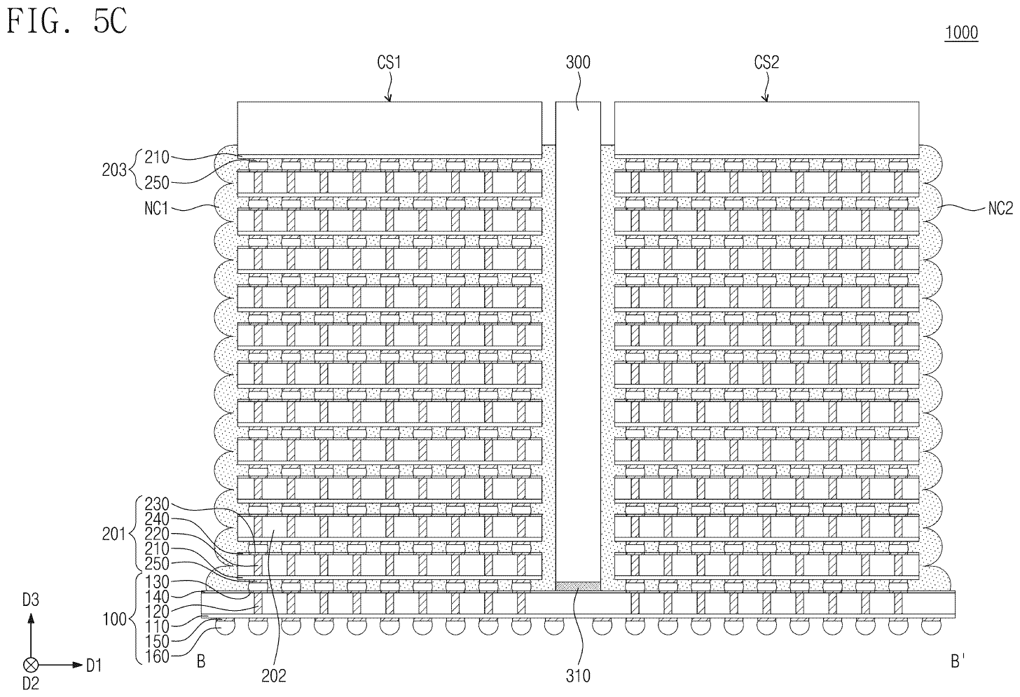

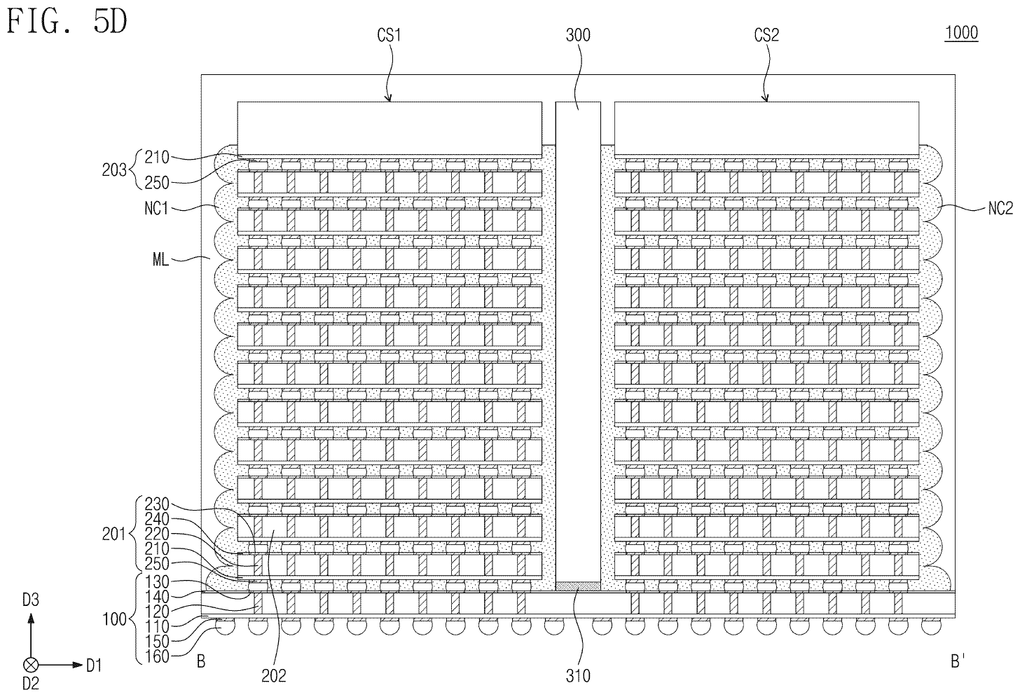

FIGS. 5A to 5D illustrate a method of fabricating a semiconductor package according to some example embodiments.

Referring to FIG. 5A, the supporting structure 300 may be stacked on the first semiconductor chip 100. A method of stacking the supporting structure 300 may not be limited to a specific method, and for example, the supporting structure 300 may be stacked on the first semiconductor chip 100 by a die bonding method using the third adhesive layer 310.

Referring to FIG. 5B, the first chip stack CS1 may be formed on the first semiconductor chip 100. Referring to FIG. 5C, the second chip stack CS2 may be formed on the first semiconductor chip 100, for example after the formation of the first chip stack CS1. The formation of the first and second chip stacks CS1 and CS2 may be performed through a thermo-compression bonding process, and this will be described in more detail below.

Referring to FIG. 5D, the molding layer ML may be formed on the first semiconductor chip 100. The molding layer ML may be formed by a molding process. The formation of the molding layer ML may include injecting a molding material and curing the molding material.

The molding layer ML may be formed to have a height larger than those of the first and second chip stacks CS1 and CS2. A height of the supporting structure 300 may be smaller or larger than or equal to that of the first chip stack CS1.

Referring back to FIG. 4A, the top surfaces of the first and second chip stacks CS1 and CS2 may be exposed to the outside. This may be achieved by recessing the molding layer ML. The recessing of the molding layer ML may be performed through a grinding process.

The top surface of the supporting structure 300 may or may not be exposed, depending on a height difference between the supporting structure 300 and the first and second chip stacks CS1 and CS2. In the case where the height of the supporting structure 300 is smaller than the height of both the first and second chip stacks CS1 and CS2, the supporting structure 300 may not be ground, and the molding layer ML may cover the top surface of the supporting structure 300. By contrast, in the case where the height of the supporting structure 300 is larger than the height of both the first and second chip stacks CS1 and CS2, the supporting structure 300 may be ground, and the top surfaces of the molding layer ML, the first and second chip stacks CS1 and CS2, and the supporting structure 300 may be exposed to the outside.

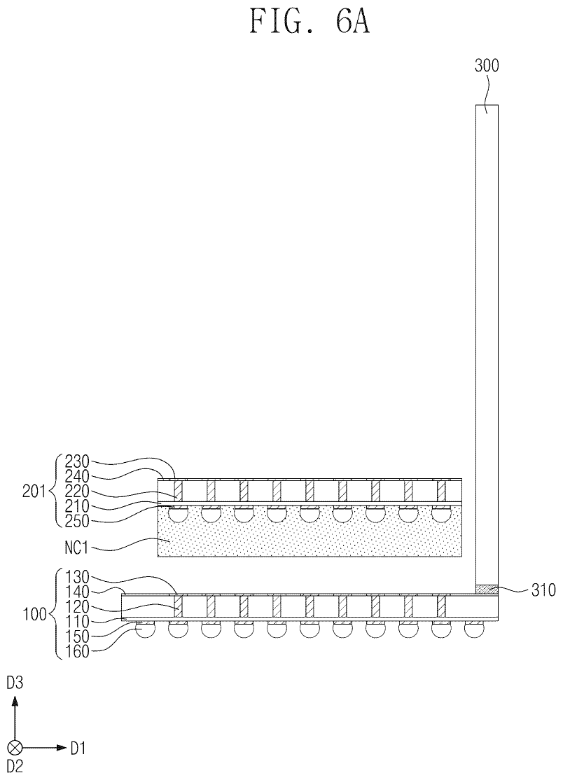

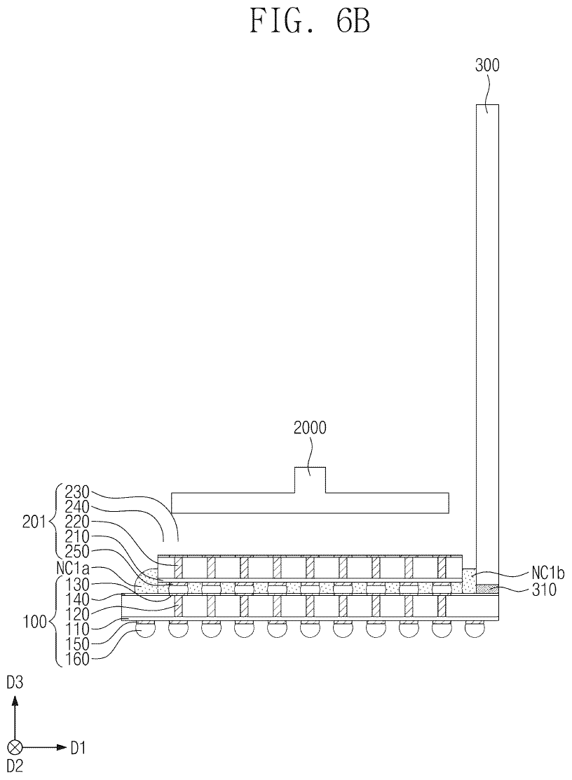

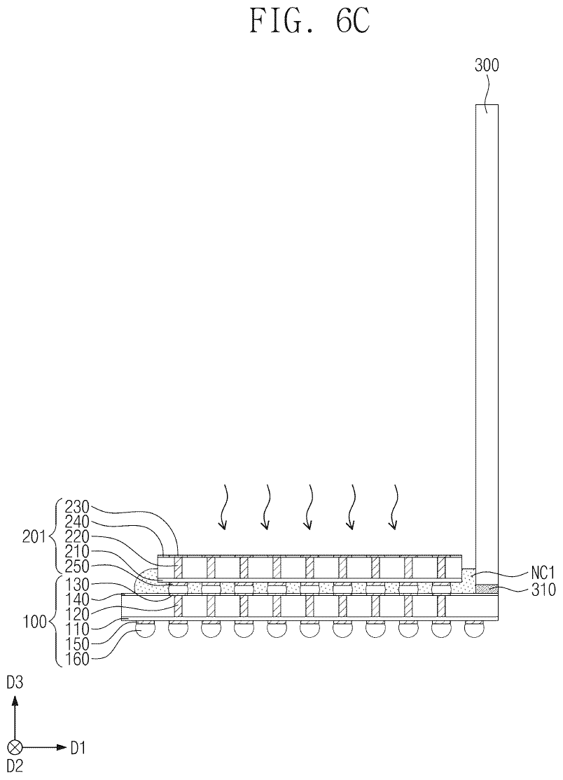

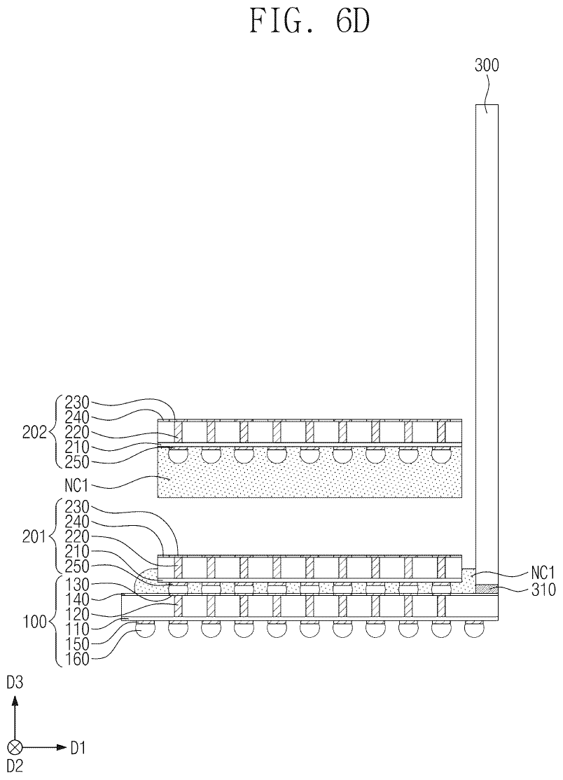

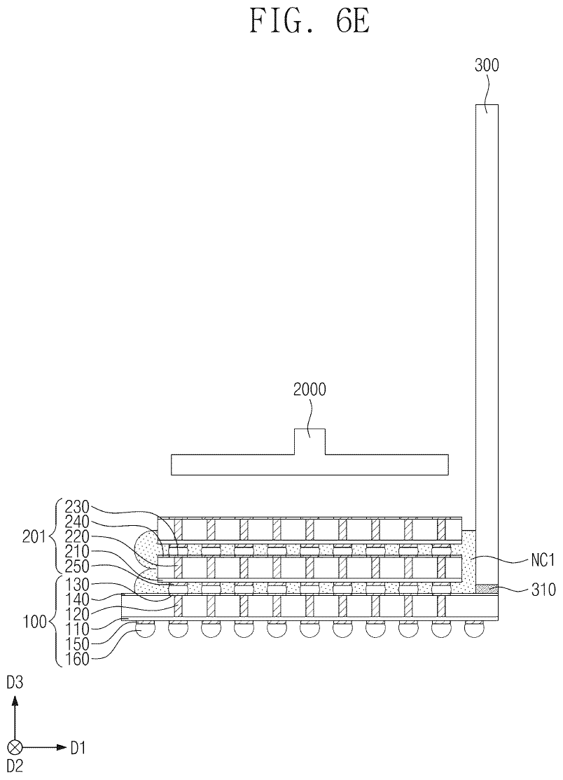

FIGS. 6A to 6E illustrate a method of fabricating a memory chip stack in a semiconductor package according to some example embodiments.

The first and second chip stacks CS1 and CS2 may be formed by repeating a process to be described below. FIGS. 6A to 6E exemplarily illustrate a process of forming the first chip stack CS1.

Referring to FIG. 6A, the lower semiconductor chip 201 may be provided on the first semiconductor chip 100. The chip terminals 320 and an adhesive layer NC1 enclosing them may be provided on the bottom surface of the lower semiconductor chip 201. Alternatively, although not shown, the chip terminals 320 may be provided on the bottom surface of the lower semiconductor chip 201, and the adhesive layer NC1 may be provided on the top surface of the first semiconductor chip 100. In the case where the adhesive layer NC1 is or includes a non-conductive paste agent, the adhesive layer NC1 may be formed by coating a liquid non-conductive paste agent using a dispensing method. In the case where the adhesive layer NC1 is or includes a non-conductive film, the adhesive layer NC1 may be formed by attaching the non-conductive film.

Referring to FIG. 6B, the lower semiconductor chip 201 may be bonded to the first semiconductor chip 100 through a thermo-compression bonding process. For example, a width of a bonding tool 2000, which is used for the bonding process, may be less than a width of a memory chips.

In the case where the lower semiconductor chip 201 is compressed toward the first semiconductor chip 100, the adhesive layers NC1 may protrude to the outside of the side surface of the lower semiconductor chip 201. In detail, the first portion NC1a, which is spaced apart from the supporting structure 300 in the first direction D1, may protrude in a direction away from the supporting structure 300. By contrast, compared with the first portion NC1a, the second portion NC1b, which is interposed between the lower semiconductor chip 201 and the supporting structure 300, may not protrude, due to the presence of the supporting structure 300. As a result, height of the second portion NC1b may be equal to or larger than the first portion NC1a.

Referring to FIG. 6C, a first thermal treatment process may be performed on the lower semiconductor chip 201. The adhesive layer NC1 between the first and lower semiconductor chips 100 and 201 may be partially hardened or cured by the first thermal treatment process.

Referring to FIG. 6D, the intermediate semiconductor chip 202 may be provided on the lower semiconductor chip 201. A bottom surface of the intermediate semiconductor chip 202 may have substantially the same features as that of the lower semiconductor chip 201 of FIG. 3A.

Referring to FIG. 6E, the intermediate semiconductor chip 202 may be bonded to the lower semiconductor chip 201 through a thermo-compression bonding process. The bonding tool 2000 and the adhesive layer NC1 may be configured to have substantially the same features as those in the embodiment of FIG. 6B.

The adhesive layer NC1 on the bottom surface of the intermediate semiconductor chip 202 and the adhesive layer NC1 on the bottom surface of the lower semiconductor chip 201 may be combined to form one adhesive layer NC1.

Although not shown, a second thermal treatment process may be performed on the intermediate semiconductor chip 202. The adhesive layer NC1 between the intermediate semiconductor chip 202 and the lower semiconductor chip 201 may be partially hardened or cured by the second thermal treatment process.

The process of FIGS. 6C to 6E may be repeated to form the first chip stack CS1. Referring back to FIG. 5C, the same or a similar process may be performed to form the second chip stack CS2, after the formation of the first chip stack CS1.

In a semiconductor package according to some example embodiments, a supporting chip may be interposed between a plurality of memory chip stacks. It may be possible to prevent or reduce the likelihood of and/or impact of memory chips from being disconnected from each other by the warpage of the semiconductor package. As a result, the reliability of the semiconductor package may be improved.

Due to the presence of the supporting chip, non-conductive layers of memory chip stacks facing each other may be flat. Thus, the formation of void between the non-conductive layers may be reduced. As a result, the durability of the semiconductor package may be improved.

While some example embodiments have been particularly shown and described, it will be understood by one of ordinary skill in the art that variations in form and detail may be made therein without departing from the spirit and scope of the attached claims. Additionally, example embodiments are not necessarily mutually exclusive with one another. For example, some example embodiments may include one or more features described with reference to one or more figures, and may also include one or more other features described with reference to one or more other figures.

What is claimed is:

1. A semiconductor package, comprising:
a first semiconductor chip extending in a horizontal direction;
a first chip stack and a second chip stack, the first and second chip stacks on the first semiconductor chip and horizontally spaced apart from each other;
a supporting structure on the first semiconductor chip and interposed between the first and second chip stacks;
a first adhesive layer on the first semiconductor chip in contact with the first chip stack and the supporting structure; and
a second adhesive layer on the first semiconductor chip in contact with the second chip stack and the supporting structure,
wherein each of the first and second chip stacks comprises one or more second semiconductor chips stacked in a vertical direction,
each of the first and second semiconductor chips comprises a penetration via, and
the first and second adhesive layers are spaced apart from each other with the supporting structure interposed therebetween.

2. The semiconductor package of claim 1, wherein a thermal expansion coefficient (CTE) of the supporting structure is less than that of the first adhesive layer.

3. The semiconductor package of claim 1, wherein the supporting structure comprise one or both of bulk silicon or glass.

4. The semiconductor package of claim 1, wherein a distance between the first and second chip stacks in the horizontal direction is less than 400 μm.

5. The semiconductor package of claim 1, further comprising:
chip terminals connecting two adjacent ones of the second semiconductor chips, the two adjacent ones adjacent to each other in the vertical direction,
wherein the first adhesive layer fills a space between the chip terminals.

6. A semiconductor package, comprising:
a first semiconductor chip including a plurality of first penetration vias;
a first chip stack and a second chip stack, the first and second chip stacks on the first semiconductor chip and spaced apart from each other in a first direction parallel to a top surface of the first semiconductor chip;
a supporting structure on the first semiconductor chip and interposed between the first and second chip stacks;
a first adhesive layer on the first semiconductor chip in direct contact with the first chip stack and the supporting structure;
a second adhesive layer on the first semiconductor chip in direct contact with the second chip stack and the supporting structure; and
a molding layer in direct contact with the first and second adhesive layers,
wherein each of the first and second chip stacks comprises one or more second semiconductor chips, the second semiconductor chips stacked in a second direction perpendicular to the top surface of the first semiconductor chip,
each of the second semiconductor chips comprise a plurality of second penetration vias,
when viewed in a plan view, the first adhesive layer comprises a first portion interposed between the molding layer and the first chip stack and a second portion interposed between the supporting structure and the first chip stack, and
a largest value of a first width of the first portion in the first direction is larger than a second width of the second portion in the first direction.

7. The semiconductor package of claim 6, wherein a width of the first semiconductor chip in the first direction is larger than two times a width of the first chip stack in the first direction.

8. The semiconductor package of claim 6, wherein a thermal expansion coefficient (CTE) of the supporting structure is less than that of the molding layer.

9. The semiconductor package of claim 6, wherein the first adhesive layer is in direct contact with an upper semiconductor chip.

10. The semiconductor package of claim 6, wherein a height of the second portion in the second direction is equal to or greater than a height of the first portion in the second direction.

11. The semiconductor package of claim 6, wherein a height of the supporting structure in the second direction is equal to or greater than a height of the first adhesive layer in the second direction.

12. The semiconductor package of claim 6, wherein a height of the supporting structure in the second direction is equal to or less than a height of the first chip stack in the second direction.

13. The semiconductor package of claim 6, wherein a height of the supporting structure in the second direction is equal to or less than a height of the molding layer in the second direction.

14. The semiconductor package of claim 6, wherein a length of the supporting structure in a third direction perpendicular to the first and second directions is equal to or longer than a length of the first chip stack in the third direction.

15. The semiconductor package of claim 6, wherein the first adhesive layer comprises at least one of a non-conductive film (NCF) and a non-conductive paste (NCP).

16. The semiconductor package of claim 6, wherein the first width is larger than the second width, at a same level.

17. The semiconductor package of claim 6, wherein the second width is less than 200 μm.

18. A semiconductor package, comprising:
a first semiconductor chip including a plurality of first penetration vias;
a first chip stack and a second chip stack, the first and second chip stacks on the first semiconductor chip and spaced apart from each other in a first direction parallel to a top surface of the first semiconductor chip;
a supporting structure on the first semiconductor chip and interposed between the first and second chip stacks;
a first adhesive layer on the first semiconductor chip in direct contact with the first chip stack and the supporting structure;
a second adhesive layer on the first semiconductor chip in direct contact with the second chip stack and the supporting structure; and
a molding layer in direct contact with the first and second adhesive layers,
wherein each of the first and second chip stacks comprises,
one or more second semiconductor chips stacked in a second direction perpendicular to the top surface of the first semiconductor chip; and
one or more chip terminals interposed between the second semiconductor chips,
wherein each of the second semiconductor chips comprises a plurality of second penetration vias,
the first adhesive layer comprises a first portion interposed between the molding layer and the first chip stack and a second portion interposed between the supporting structure and the first chip stack, when viewed in a plan view, and
at a level overlapped with the chip terminals, a width of the first portion in the first direction is larger than a width of the second portion in the first direction.

19. The semiconductor package of claim 18, further comprising:
a third adhesive layer interposed between the supporting structure and the first semiconductor chip.

20. The semiconductor package of claim 18, wherein the mold layer comprises an epoxy molding compound (EMC) and exposes a top surface of the first chip stack.
